(19) United States
(12) Patent Application Publication
(10) Pub. No.: US 2005/0011672 A1
(43) Pub. Date: Jan. 20, 2005

(54) Overmolded MCM with increased surface mount component reliability

(76) Inventors: Ashish D. Alawani, Ladera Ranch, CA (US); Sandra L. Petty-Weeks, Newport Beach, CA (US); Lori A. DeOrio, Irvine, CA (US); Roberto U. Villanueva, Rancho Santa Margarita, CA (US)

Correspondence Address: FARJAMI & FARJAMI LLP, 26522 LA ALAMEDA AVENUE, SUITE 360, MISSION VIEJO, CA, 92691, US

(21) Appl. No.: 10/623,243

(22) Filed: Jul. 17, 2003

(51) Int. Cl. H05K 7/06

(52) U.S. Cl. 174/260

(57) ABSTRACT

According to one exemplary embodiment, an overmolded module comprises a surface mount component situated over a substrate, where the surface mount component comprises a first terminal and a second terminal. The overmolded module can be an MCM and the substrate can be a laminate circuit board, for example. The overmolded module further comprises a first and a second pad situated on the substrate, where the first pad is connected to the first terminal and the second pad is connected to the second terminal. According to this exemplary embodiment, the overmolded module further comprises a solder mask trench situated underneath the surface mount component, where the solder mask trench is filled with molding compound. The overmolded module further comprises a moldable gap situated between a bottom surface of the surface mount component and a top surface of the substrate, where the moldable gap includes the solder mask trench.

### BACKGROUND OF THE INVENTION

1. Field of the Invention

The present invention is generally in the field of semiconductor device packaging. More specifically, the invention is in the field of overmolded module packaging.

2. Related Art

Electronic devices, such as cell phones, typically utilize an MCM (multi-chip module or multi-component module) to provide a high level of circuit integration in a single molded package. The MCM can include, for example, one or more dies and a number of surface mount components (“SMCs”), which are mounted on a single circuit board. The circuit board including the SMCs can be encapsulated in a molding process to form an overmolded MCM package.

By way of background, in a conventional MCM fabrication process, solder mask is patterned and developed on a circuit board to form solder mask openings, which expose solderable areas on the circuit board, such as metal pads. A SMC can be mounted on printed circuit board by soldering the terminals of the SMC to exposed metal pads, which are situated in solder mask openings. When the SMC is mounted on the circuit board, a gap is formed between the bottom of the SMC and the solder mask, which is situated on the top surface of the circuit board.

During the molding process, a molding compound, such as an epoxy molding compound, is formed over each SMC and also fills the gap formed between the bottom of the SMC and the solder mask situated on the top surface of the circuit board. However, since the gap is relatively narrow, the molding compound may not completely fill the gap underneath the SMC. As a result, one or more voids can form in the molding compound situated underneath the SMC. After completion of the molding process, preconditioning tests are typically performed on the overmolded MCM to ensure that the overmolded MCM package meets Interconnect Packaging Committee (“IPC”)/Joint Electronic Device Engineering Council (“JEDEC”) moisture sensitivity specifications and to simulate customer handling. The preconditioning tests include a moisture soak and reflow test, which can cause the solder that secures the terminals of the SMC to the circuit board to melt. As a result, solder can flow into any voids that were formed in the molding compound underneath the SMC during the molding process and cause the terminals of the SMC to short and, thereby, cause the SMC to fail. Thus, voids formed underneath a SMC reduce the reliability of the SMC and, consequently, reduce the reliability of the overmolded MCM that includes the SMC.

Thus, there is a need in the art for more a more reliable SMC in an overmolded MCM.

### SUMMARY OF THE INVENTION

The present invention is directed to overmolded MCMs with increased surface mount component reliability. The present invention addresses and resolves the need in the art for a more reliable SMC in an overmolded MCM.

According to one exemplary embodiment, an overmolded module comprises a surface mount component situated over a substrate, where the surface mount component comprises a first terminal and a second terminal. For example, the overmolded module can be an MCM and the substrate can be a laminate circuit board. The surface mount component may be a resistor, a capacitor, or an inductor, for example. The overmolded module further comprises a first and a second pad situated on the substrate, where the first pad is connected to the first terminal and the second pad is connected to the second terminal.

According to this exemplary embodiment, the overmolded module further comprises a solder mask trench situated underneath the surface mount component, where the solder mask trench is filled with molding compound. The overmolded module further comprises a moldable gap situated between a bottom surface of the surface mount component and a top surface of the substrate, where the moldable gap includes the solder mask trench; the moldable gap can be filled with the molding compound. The overmolded module further comprises an encapsulation or molding process to form an overmolded package, where the overmold is situated over and under the surface mount component. Other features and advantages of the present invention will become more readily apparent to those of ordinary skill in the art after reviewing the following detailed description and accompanying drawings.

### BRIEF DESCRIPTION OF THE DRAWINGS

FIG. 1 illustrates a cross sectional view of an exemplary structure including an exemplary surface mount component in accordance with one embodiment of the present invention.

FIG. 2 illustrates an exemplary surface mount component layout in accordance with one embodiment of the present invention.

FIG. 3 illustrates a cross sectional view of an exemplary structure including an exemplary surface mount component in accordance with one embodiment of the present invention.

### DETAILED DESCRIPTION OF THE INVENTION

The present invention is directed to overmolded MCMs with increased surface mount component reliability. The following description contains specific information pertaining to the implementation of the present invention. One skilled in the art will recognize that the present invention may be implemented in a manner different from that specifically discussed in the present application. Moreover, some of the specific details of the invention are not discussed in order not to obscure the invention.

The drawings in the present application and their accompanying detailed description are directed to merely exemplary embodiments of the invention. To maintain brevity, other embodiments of the present invention are not specifically described in the present application and are not specifically illustrated by the present drawings. It is noted that although an exemplary SMC is utilized to illustrate the present invention, the present invention also applies to two or more SMCs and/or other surface mount components that have more than two terminals (also referred to as a “surface mount device” in the present application), as well as variations of the invention necessary for assembling multiple SMCs in an overmolded or encapsulated MCM.

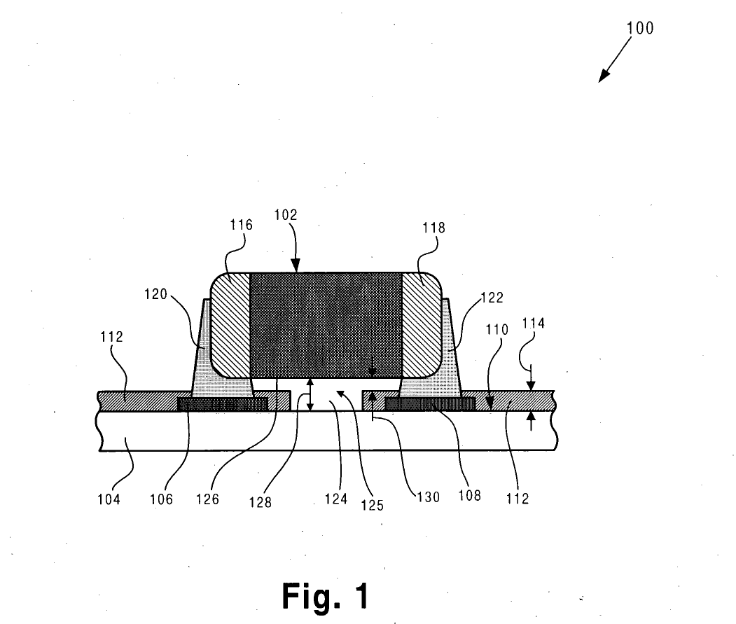

FIG. 1 shows a cross-sectional view of structure 100, which is utilized to describe one embodiment of the present invention. Certain details and features have been left out of FIG. 1 that are apparent to a person of ordinary skill in the art. Structure 100 includes SMC 102, which is situated on substrate 104, and can be, for example, an MCM, i.e. a multi-chip module or a multi-component module. It is noted that although only one SMC is shown in FIG. 1 to preserve brevity, structure 100 can comprise any number of SMCs.

As shown in FIG. 1, pads 106 and 108 are situated on top surface 110 of substrate 104, which can be, for example, a laminate circuit board. Pads 106 and 108 can comprise a metal, such as copper, and can be patterned on top surface 110 of substrate 104 in a manner known in the art. Also shown in FIG. 1, solder mask 112 is situated on top surface 110 of substrate 104 and may or may not be over portions of pads 108 and 106 and can comprise an appropriate masking material as known in the art. Solder mask 112 can have thickness 114, which can be, for example, between approximately 30.0 and 55.0 micrometers.

Further shown in FIG. 1, terminal 116 of SMC 102 is attached to pad 106 by solder joint 120 and terminal 118 of SMC 102 is attached to pad 108 by solder joint 122. SMC 102 can be, for example, a passive component like a resistor, a capacitor, or an inductor and/or can be a discrete or active component like a diplexer, diode, or SAW (Surface Acoustic Wave) filter and can comprise a ceramic material, plastic material, or other appropriate material as known in the art. Terminals 116 and 120 of SMC 102 can comprise metal, which can be plated on respective ends of SMC 102 in a manner known in the art. In one embodiment, terminals 116 and 120 can be situated underneath SMC 102, for example, in a land grid array pattern. Solder joints 120 and 122 are utilized to form a mechanical and electrical connection between terminals 116 and 118 of SMC 102 and pads 106 and 108, respectively.

Also shown in FIG. 1, solder mask trench 124 is situated between bottom surface 126 of SMC 102 and top surface 110 of substrate 104 and between pads 106 and 108 of SMC 102. Solder mask trench 124 can be formed by appropriately patterning and developing an opening in solder mask 112. In the present embodiment, solder mask trench 124 is formed over a non-solderable area on substrate 104. In contrast, a conventional solder mask opening is formed only over a solderable area or to expose an interconnect area on substrate 104. Further shown in FIG. 1, moldable gap 125 is situated between bottom surface 126 of SMC 102 and top surface 110 of substrate 104 and includes solder mask trench 124. Moldable gap 125 can be filled with molding compound in a molding process and has height 128, which can be, for example, between approximately 45.0 and 65.0 micrometers.

Thus, by forming solder mask trench 124 underneath SMC 102, the present invention achieves a moldable gap, i.e. moldable gap 125, that is significantly larger than a conventional moldable gap. For example, in a conventional process, solder mask 112 would extend between pads 106 and 108 underneath SMC 102. As a result, a conventional moldable gap that would be formed between solder mask 112 and bottom surface 126 of SMC 102 would have a height equal to height 130, which can be, for example, between approximately 10.0 and 25.0 micrometers. Thus, by forming solder mask trench 124, the present invention advantageously achieves a significantly larger moldable gap that improves molding compound flow underneath SMC 102 and, consequently, minimizes void formation underneath SMC 102. As a result, the present invention advantageously minimizes the risk of shorting between terminals 120 and 122, during, for example, reflow assembly, which increases the reliability of SMC 102.

In one embodiment, a structure, such as an MCM, can comprise a surface mount device situated over a substrate, such as substrate 104, where the surface mount device comprises more than two terminals, and where each of the more than two terminals is connected to a respective pad situated on the top surface of the substrate. In that embodiment, a solder mask trench can be situated underneath the surface mount device and can provide similar advantages as discussed above in relation to the embodiment of the present invention in FIG. 1. The surface mount device can be a leadless surface mount device and can comprise, for example, a diplexer, a low pass filter, a bandpass filter, SAW filter or a discrete or active packaged device like a diode. In one embodiment, the surface mount device discussed above can be a packaged leaded device.

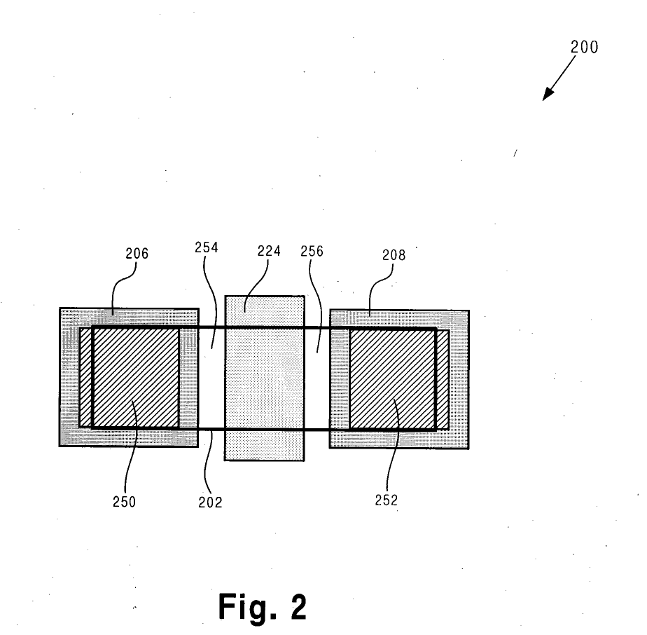

FIG. 2 shows an exemplary layout of structure 100 in FIG. 1 in accordance with one embodiment of the present invention. In particular, SMC 202, pads 206 and 208, and solder mask trench 224 in layout 200 in FIG. 2 correspond, respectively, to SMC 102, pads 106 and 108, and solder mask trench 124 in structure 100 in FIG. 1. It is noted that in FIG. 2 solder mask, such as solder mask 112 in FIG. 1, surrounds but is not situated in solder mask trench 224 and solder mask openings 250 and 252. As shown in FIG. 2, solder mask openings 250 and 252 are situated over pads 206 and 208, respectively, and can be formed by patterning and developing appropriate openings in solder mask, such as solder mask 112 in FIG. 1. Solder mask openings 250 and 252 expose portions of respective pads 206 and 208 such that the exposed portions of pads 206 and 208 can be soldered to respective terminals of SMC 202.

Also shown in FIG. 2, solder mask area 254 is situated between pad 206 and solder mask trench 224 and solder mask area 256 is situated between pad 208 and solder mask trench 224. In one embodiment, solder mask trench 224 is extended to the edges of pads 206 and 208 such that solder mask area 254 and 256 are eliminated. In one embodiment, solder mask trench 224 surrounds pads 206 and 208 and includes the area between pads 206 and 208 such that pads 206 and 208 are completely exposed in solder mask trench 224. Further shown in FIG. 2, SMC 202 is situated over solder mask openings 250 and 252 and over solder mask trench 224.

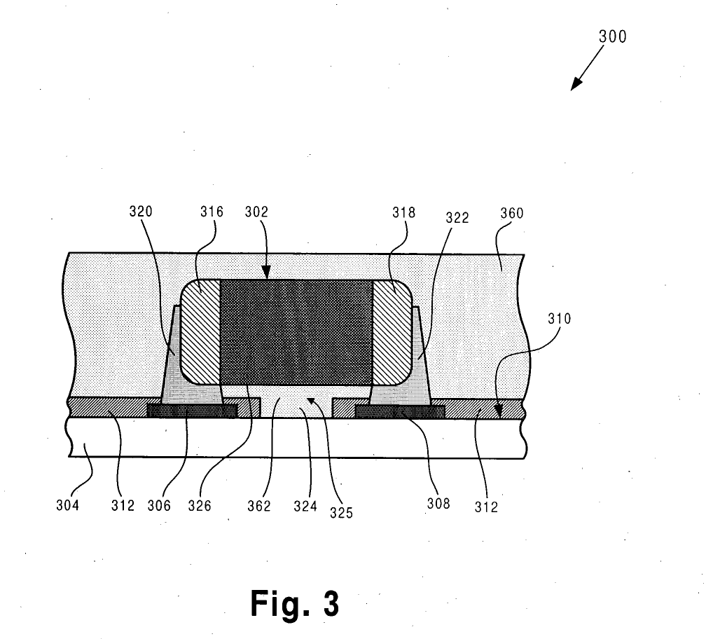

FIG. 3 shows a cross-sectional view of structure 100 in FIG. 1 after molding compound has been applied in accordance with one embodiment of the present invention. In FIG. 3, substrate 304, pads 306 and 308, top surface 310, solder mask 312, terminals 316 and 318, solder joints 320 and 322, solder mask trench 324, moldable gap 325, and bottom surface 326 in structure 300 correspond, respectively, to substrate 104, pads 106 and 108, top surface 110, solder mask 112, terminals 116 and 118, solder joints 120 and 122, solder mask trench 124, moldable gap 125, and bottom surface 126 in structure 100 in FIG. 1.

As shown in FIG. 3, overmold 360 is situated over solder mask 312 and over SMC 302. Overmold 360 can comprise an epoxy molding compounding or other appropriate molding compound and can be formed in a molding process in a manner known in the art. Also shown in FIG. 3, undermold 362 is situated in moldable gap 325, which includes solder mask trench 324. Undermold 362 can comprise a similar molding compound as overmold 360 discussed above and can be formed by filling moldable gap 325 with molding compound in a molding process in a manner known in the art. Overmold 360 and undermold 362 may or may not be achieved during the same molding/encapsulation process in a manner known in the art.

By forming solder mask trench 324, the present invention advantageously achieves a moldable gap underneath SMC 302 that is more easily filled with molding compound, which reduces the risk of forming voids in the moldable gap during the molding process. As a result, the present invention advantageously achieves a SMC having increased reliability. Additionally, by utilizing solder mask trench 324 to increase the size of the moldable gap, i.e. moldable gap 325, the present invention advantageously achieves a more consistent mold-fill, i.e. undermold 362, between solder joints 320 and 322.

It is appreciated by the above detailed description that the invention provides a SMC having increased reliability, where the SMC is situated in a structure, such as an overmolded MCM. From the above description of the invention it is manifest that various techniques can be used for implementing the concepts of the present invention without departing from its scope. Moreover, while the invention has been described with specific reference to certain embodiments, a person of ordinary skill in the art would appreciate that changes can be made in form and detail without departing from the spirit and the scope of the invention. Thus, the described embodiments are to be considered in all respects as illustrative and not restrictive. It should also be understood that the invention is not limited to the particular embodiments described herein but is capable of many rearrangements, modifications, and substitutions without departing from the scope of the invention.

Thus, overmolded MCM with increased surface mount component reliability has been described.

1. An overmolded module comprising:
a surface mount component situated over a substrate, said surface mount component comprising a first terminal and a second terminal;
a first and a second pad situated on said substrate, said first pad being connected to said first terminal and said second pad being connected to said second terminal;
a solder mask trench situated underneath said surface mount component, said solder mask trench being filled with molding compound said solder mask trench formed within a solder mask.

2. The overmolded module of claim 1 further comprising a moldable gap situated between a bottom surface of said surface mount component and a top surface of said substrate, said moldable gap including said solder mask trench.

3. The overmolded module of claim 2 wherein said moldable gap is filled with said molding compound.

4. The overmolded module of claim 1 further comprising an overmold, said overmold being situated over said surface mount component.

5. The overmolded module of claim 1 wherein said surface mount component is selected from the group consisting of a resistor, a capacitor, an inductor, a diplexer, a diode, and a SAW filter.

6. The overmolded module of claim 3 wherein said moldable gap has a height of between approximately 45.0 micrometers and 65.0 micrometers.

7. The overmolded module of claim 1 wherein said overmolded module is an MCM.

8. The overmolded module of claim 1 wherein said substrate comprises a laminate circuit board.

9. An overmolded module comprising:
a surface mount component situated over a substrate, said surface mount component comprising a first terminal and a second terminal;
a first and a second pad situated on said substrate, said first pad being connected to said first terminal and said second pad being connected to said second terminal;
a moldable gap situated underneath said surface mount component, said moldable gap comprising a solder mask trench, said solder mask trench being filled with molding compound, said solder mask trench formed within a solder mask.

10. The overmolded module of claim 9 wherein said moldable gap is filled with said molding compound.

11. The overmolded module of claim 9 further comprising an overmold, said overmold being situated over said surface mount component.

12. The overmolded module of claim 11 wherein said overmold comprises said molding compound.

13. The overmolded module of claim 9 wherein said moldable gap has a height of between approximately 45.0 micrometers and 65.0 micrometers.

14. The overmolded module of claim 9 wherein said surface mount component is selected from the group consisting of a resistor, a capacitor, an inductor, a diplexer, a diode, and a SAW filter.

15. The overmolded module of claim 9 wherein said overmolded module is an MCM.

16. An overmolded module comprising:
a surface mount device situated over a substrate, said surface mount device comprising a plurality of terminals;
a plurality of pads situated on said substrate, each of said plurality of pads being connected to a respective one of said plurality of terminals;
a solder mask trench situated underneath said surface mount device, said solder mask trench being filled with molding compound, said solder mask trench formed within a solder mask.

17. The overmolded module of claim 16 wherein said surface mount device is a leaded surface mount device.

18. The overmolded module of claim 16 wherein said surface mount device is a leadless surface mount device.

19. The overmolded module of claim 16 wherein said surface mount device comprises at least one component, said at least one component being selected from the group consisting of an active component and a passive component.

20. The overmolded module of claim 16 wherein said overmolded module is an MCM.
